(19) United States
(12) Patent Application Publication
(10) Pub. No.: US 2026/0013254 A1
(43) Pub. Date: Jan. 8, 2026

(54) SEMICONDUCTOR PACKAGE AND METHOD OF FABRICATING THE SAME

(71) Applicant: Samsung Electronics Co., Ltd., Suwon-si (KR)

(72) Inventors: JinGyu SHIN, Suwon-si (KR); Jing Cheng LIN, Suwon-si (KR); YOUNG KUN JEE, Suwon-si (KR); Yu Jen CHEN, Suwon-si (KR)

(21) Appl. No.: 19/029,743

(22) Filed: Jan. 17, 2025

(30) Foreign Application Priority Data
Jul. 3, 2024 (KR) 10-2024-0087615

(51) Int. Cl. H10F 39/00; H01L 23/31; H01L 23/48; H01L 25/16; H10F 39/95

(52) U.S. Cl. CPC H10F 39/8063; H01L 25/167; H10F 39/024; H10F 39/804; H10F 39/811; H10F 39/95; H01L 23/3135; H01L 23/481

(57) ABSTRACT

A semiconductor package includes a first chip structure on a first substrate and a first molding layer surrounding the first chip structure on the first substrate, wherein the first chip structure includes a first chip including a PIC on the first substrate, a second chip including an EIC on the first chip, a transparent layer horizontally spaced from the second chip on the first chip, a microlens layer on the transparent layer; and a second molding layer surrounding the second chip, the transparent layer, and the microlens layer on the first chip, the semiconductor package further includes a first insulating layer on an upper surface of the first chip and a second insulating layer on a lower surface of the transparent layer, and the first and second 10 insulating layers are in contact with each other, and the first and second insulating layers are integrally formed of the same material.

### CROSS-REFERENCE TO RELATED APPLICATIONS

This U.S. non-provisional patent application claims priority under 35 U.S.C. § 119 to Korean Patent Application No.10-2024-0087615 filed on Jul. 3, 2024, in the Korean Intellectual Property Office, the entire contents of which are hereby incorporated by reference.

### BACKGROUND OF THE INVENTION

Aspects of the inventive concept relate to a semiconductor package and a method of fabricating the same, and more specifically, to a semiconductor package including an optical element and a method of fabricating the same.

High-performance, high-speed, and small electronic components have been increasingly demanded with the development of the electronics industry. To satisfy these demands, a packaging technique of providing a plurality of semiconductor chips in a single package has been suggested.

Recently, portable devices have been increasingly demanded in the electronics market, and thus small and light electronic components mounted in the electronics have been used. A semiconductor package technique of integrating a plurality of individual components in a single package as well as a technique of reducing a size of an individual component may be desirable to realize small and light electronic components. In particular, semiconductor packages in which a plurality of elements are integrated benefit from various structural, electrical, and optical characteristics depending on the characteristics and functions of the elements.

### SUMMARY

An object of the inventive concept is to provide a semiconductor package with improved structural stability and a method of fabricating the same.

An object of the inventive concept is to provide a semiconductor package with improved optical characteristics and a method of fabricating the same.

An object of the inventive concept is to provide a semiconductor package with a simple structure and a miniaturized structure and a method of fabricating the same.

The problem that the inventive concept seeks to solve is not limited to the problems mentioned above, and other problems and/or solutions that are not mentioned may be clearly understood by those skilled in the art from the description below.

A semiconductor package according to some embodiments of the inventive concept may include a first substrate, a first chip structure mounted on the first substrate, and a first molding layer surrounding the first chip structure on the first substrate, wherein the first chip structure includes a first chip on the first substrate, the first chip including a photonic integrated circuit (PIC), a second chip on the first chip, the second chip including an electronic integrated circuit (EIC), a transparent layer horizontally spaced from the second chip on the first chip, a microlens layer on the transparent layer, and a second molding layer surrounding the second chip, the transparent layer, and the microlens layer on the first chip, the semiconductor package further includes a first insulating layer provided on an upper surface of the first chip, the semiconductor package further includes a second insulating layer provided on a lower surface of the transparent layer, and the first insulating layer and the second insulating layer are in contact with each other, and the first insulating layer and the second insulating layer are integrally formed of the same first material.

A semiconductor package according to some embodiments of the inventive concept may include a package substrate; an interposer substrate mounted on the package substrate; a first chip mounted on the interposer substrate, the first chip including a photonic integrated circuit (PIC); a second chip on the first chip, the second chip including an electronic integrated circuit (EIC); a transparent layer on the first chip, the transparent layer being spaced apart horizontally from the second chip; a microlens layer disposed on the transparent layer; a first molding layer surrounding the second chip, the transparent layer, and the microlens layer on the first chip; a chip stack and a third chip spaced apart from the first chip on the interposer substrate; and a second molding layer surrounding the first chip, the first molding layer, the chip stack, and the third chip on the interposer substrate, wherein the chip stack includes fourth chips that are vertically stacked, wherein the semiconductor package further comprises a first insulating layer on an upper surface of the transparent layer, wherein the semiconductor package further comprises a second insulating layer on a lower surface of the microlens layer, and wherein the first insulating layer and the second insulating layer are in contact with each other, and the first insulating layer and the second insulating layer are integrally formed of the same first material.

A method of fabricating a semiconductor package according to some embodiments of the inventive concept may include providing a first chip, the first chip including a photonic integrated circuit (PIC), the first chip including first chip pads disposed on an active surface of the first chip, a sensor disposed on the active surface of the first chip, and a first insulating layer covering the active surface of the first chip and exposing the first chip pads; mounting a second chip on the first chip to be connected to the first chip pads, the second chip including an electronic integrated circuit (EIC); providing a transparent layer; forming a second insulating layer on a lower surface of the transparent layer and a third insulating layer on an upper surface of the transparent layer, the second insulating layer being formed of the same first material as the first insulating layer; bringing the first chip into contact with the transparent layer so that the first insulating layer and the second insulating layer are bonded to each other and integrally formed on the sensor; providing a microlens layer; forming a fourth insulating layer on a lower surface of the microlens layer, the fourth insulating layer being formed of the same second material as the third insulating layer; bringing the transparent layer into contact with the microlens layer so that the third insulating layer and the fourth insulating layer are bonded to each other and integrally formed; forming a molding layer covering the second chip, the transparent layer, and the microlens layer on the first chip; and performing a thinning process on the molding layer to expose an upper surface of the second chip and an upper surface of the microlens layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view for illustrating a semiconductor package according to embodiments of the inventive concept.

FIG. 2 and FIG. 4 are enlarged views of region ‘A’ of FIG. 1.

FIG. 3 and FIG. 5 are enlarged views of region ‘B’ of FIG. 1.

FIG. 6 to FIG. 12 are cross-sectional views for illustrating a semiconductor package according to embodiments of the inventive concept.

FIG. 13 to FIG. 24 are cross-sectional views for illustrating a method of fabricating a semiconductor package according to embodiments of the inventive concept.

### DETAILED DESCRIPTION

A semiconductor package according to the inventive concept is described with reference to the drawings.

It will be understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

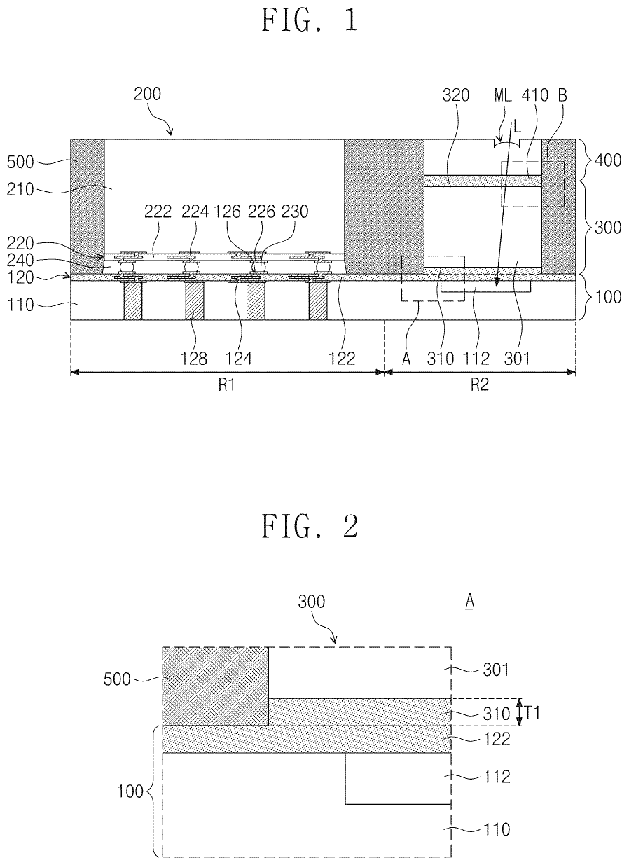

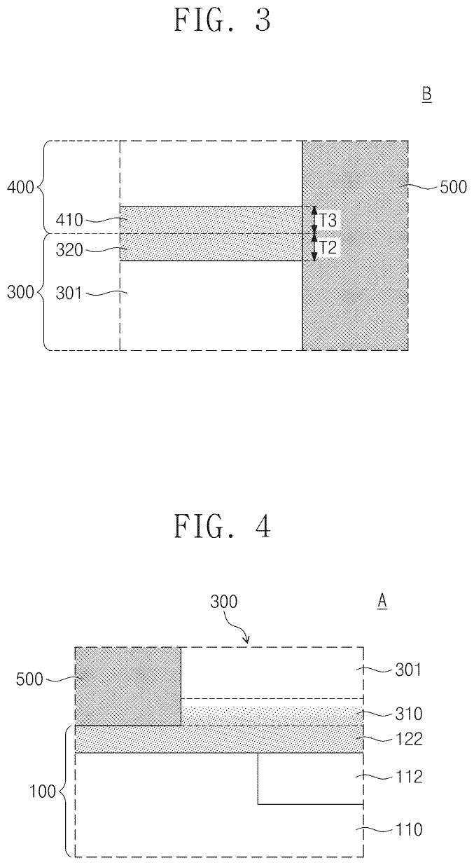

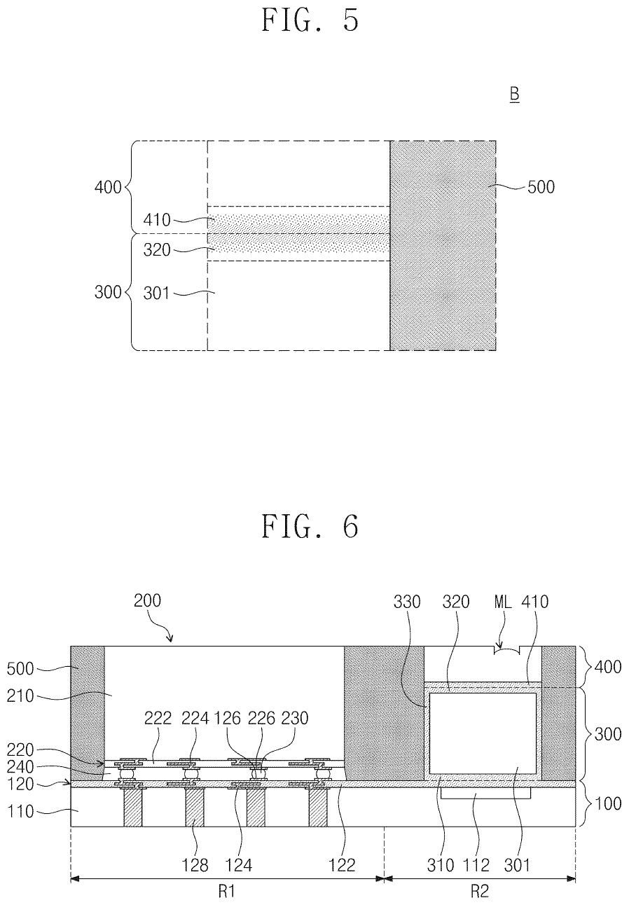

FIG. 1 is a cross-sectional view for illustrating a semiconductor package according to embodiments of the inventive concept. FIG. 2 and FIG. 4 are enlarged views of region ‘A’ of FIG. 1. FIG. 3 and FIG. 5 are enlarged views of region ‘B’ of FIG. 1.

Referring to FIG. 1, a first chip 100 may be provided. The first chip 100 may include an integrated element therein. For example, the first chip 100 may be a wafer level die formed of a semiconductor such as silicon (Si). An upper surface of the first chip 100 may be an active surface. That is, the first chip 100 may be provided face up.

The first chip 100 may include a first semiconductor substrate 110, a first circuit layer 120, and chip vias 128.

The first semiconductor substrate 110 may be provided. The first semiconductor substrate 110 may include a semiconductor material. For example, the first semiconductor substrate 110 may be a silicon (Si) single crystal substrate. The first semiconductor substrate 110 may have upper and lower surfaces opposite to each other. The upper surface of the first semiconductor substrate 110 may be a front surface of the first semiconductor substrate 110, and the lower surface of the first semiconductor substrate 110 may be a back surface of the first semiconductor substrate 110. Here, the front surface of the first semiconductor substrate 110 may be defined as one side of the first semiconductor substrate 110 on which integrated elements are formed or mounted, or wiring, pads, etc. are formed, and the back surface of the first semiconductor substrate 110 may be defined as a side opposite to the front surface.

The first chip 100 may have a first integrated element provided on the upper surface of the first semiconductor substrate 110. The first integrated element may include a photonic integrated circuit (PIC).

The first semiconductor substrate 110 may have a first region R1 and a second region R2 that are disposed to be horizontally spaced from each other. The first region R1 may be a region on which a second chip 200 described below is mounted. The second region R2 may be a region where a support block 300 and a microlens layer 400 described below are disposed. That is, the first region R1 may be a region where the first chip 100 receives an electrical signal from the second chip 200, and the second region R2 may be a region where the first chip 100 receives an optical signal from the outside (e.g., from a source external to the semiconductor package).

The first semiconductor substrate 110 may further include a sensor 112. The sensor 112 may be disposed on the second region R2. The sensor 112 may be exposed on the upper surface of the first semiconductor substrate 110. The sensor 112 may receive light and convert the light into an electrical signal.

The first chip 100 may include the first circuit layer 120 provided on the upper surface of the first semiconductor substrate 110. The first circuit layer 120 may include a first insulating layer 122 and a first element wiring portion 124.

An upper surface of the first semiconductor substrate 110 may be covered with the first insulating layer 122. The first insulating layer 122 may cover a first integrated element and the sensor 112 formed on the first semiconductor substrate 110. That is, the first integrated element and the sensor 112 may not be exposed by the first insulating layer 122. The first insulating layer 122 may include an oxide of a material constituting the first semiconductor substrate 110, a nitride of the material constituting the first semiconductor substrate 110, or an oxynitride of the material constituting the first semiconductor substrate 110. The first insulating layer 122 may include, for example, at least one of silicon oxide (SiO), silicon nitride (SiN), and silicon oxynitride (SiON).

The first element wiring portion 124 connected to the first integrated element may be provided in the first insulating layer 122. The first element wiring portion 124 may be disposed on the first region R1. The first element wiring portion 124 may include wiring patterns embedded in the first insulating layer 122. For example, the wiring patterns may include redistribution patterns for horizontal wiring and via patterns for vertical connection. The first element wiring portion 124 may vertically penetrate the first insulating layer 122 and be connected to the first integrated element. The first element wiring portion 124 may be disposed between the upper surface and the lower surface of the first insulating layer 122. The first element wiring portion 124 may include, for example, copper (Cu) or tungsten (W).

First chip pads 126 may be provided on the upper surface of the first insulating layer 122. The first chip pads 126 may be disposed on the first region R1. The first chip pads 126 may be exposed on the upper surface of the first insulating layer 122. The first chip pads 126 may protrude from the upper surface of the first insulating layer 122. Alternatively, the upper surface of the first chip pads 126 may be coplanar with the upper surface of the first insulating layer 122. The first chip pads 126 may be connected to the first element wiring portion 124. The first chip pads 126 may include, for example, copper (Cu) or tungsten (W).

The first chip 100 may further include chip vias 128 that vertically penetrate the first semiconductor substrate 110 and are connected to the first element wiring portion 124 or the first integrated element. The chip vias 128 may be disposed on the first region R1. The chip vias 128 may be patterns for vertical wirings. The chip vias 128 may vertically penetrate the first semiconductor substrate 110 and be connected to a lower surface of a portion of the first element wiring portion 124. The chip vias 128 may vertically penetrate the first semiconductor substrate 110 and be exposed on the lower surface of the first semiconductor substrate 110. The first semiconductor substrate 110 may include, for example, tungsten (W).

A second chip 200 may be provided on the first chip 100. The second chip 200 may be disposed on the first region R1. The second chip 200 may include an integrated element therein. For example, the second chip 200 may be a wafer level die formed of a semiconductor such as silicon (Si). A lower surface of the second chip 200 may be an active surface. That is, the second chip 200 may be provided face down.

The second chip 200 may include a second semiconductor substrate 210 and a second circuit layer 220.

The second semiconductor substrate 210 may be provided. The second semiconductor substrate 210 may include a semiconductor material. For example, the second semiconductor substrate 210 may be a silicon (Si) single crystal substrate. The second semiconductor substrate 210 may have upper and lower surfaces opposite to each other. The lower surface of the second semiconductor substrate 210 may be a front surface of the second semiconductor substrate 210, and the upper surface of the second semiconductor substrate 210 may be a back surface of the second semiconductor substrate 210.

The second chip 200 may have a second integrated element provided on the lower surface of the second semiconductor substrate 210. The second integrated element may include an electronic integrated circuit (EIC).

The second chip 200 may include the second circuit layer 220 provided on the lower surface of the second semiconductor substrate 210. The second circuit layer 220 may include a second insulating layer 222 and a second element wiring portion 224.

A lower surface of the second semiconductor substrate 210 may be covered with the second insulating layer 222. The second insulating layer 222 may cover the second integrated element formed on the second semiconductor substrate 210. That is, the second integrated element may not be exposed by the second insulating layer 222. The second insulating layer 222 may include, for example, at least one of silicon oxide (SiO), silicon nitride (SiN), and silicon oxynitride (SiON).

The second element wiring portion 224 connected to a second integrated element may be provided in the second insulating layer 222. The second element wiring portion 224 may include wiring patterns embedded in the second insulating layer 222. For example, the wiring patterns may include redistribution patterns for horizontal wiring and via patterns for vertical connection. The second element wiring portion 224 may vertically penetrate the second insulating layer 222 and be connected to the second integrated element. The second element wiring portion 224 may be disposed between the upper surface and the lower surface of the second insulating layer 222. The second element wiring portion 224 may include, for example, copper (Cu) or tungsten (W).

Second chip pads 226 may be provided on a lower surface of the second insulating layer 222. The second chip pads 226 may be exposed on the lower surface of the second insulating layer 222. The second chip pads 226 may protrude from a lower surface of the second insulating layer 222. Alternatively, a lower surface of the second chip pads 226 may be coplanar with the lower surface of the second insulating layer 222. The second chip pads 226 may be connected to the second element wiring portion 224. The second chip pads 226 may include, for example, copper (Cu) or tungsten (W).

The second chip 200 may be mounted on the first chip 100. The second chip 200 may be mounted on the first chip 100 in a flip chip manner. For example, the second chip 200 may be disposed on the first circuit layer 120 of the first chip 100 on the first region R1. The second circuit layer 220 of the second chip 200 may face the upper surface of the first chip 100. The second chip pads 226 of the second chip 200 may be vertically aligned with the first chip pads 126 of the first chip 100. First connection terminals 230 may be provided between the first chip pads 126 and the second chip pads 226. The first connection terminals 230 may be connected to an upper surface of the first chip pads 126 and a lower surface of the second chip pads 226. The second chip 200 may be electrically connected to the first chip 100 through the first connection terminals 230.

A first underfill layer 240 may be provided between the first chip 100 and the second chip 200. The first underfill layer 240 may fill a space between the first chip 100 and the second chip 200 and surround the first connection terminals 230.

A support block 300 may be provided on the first chip 100. The support block 300 may be disposed on the second region R2. The support block 300 may be disposed to be horizontally spaced from the second chip 200. The support block 300 may be disposed on the sensor 112. The support block 300 may cover the entire sensor 112. The support block 300 may transmit light that the first chip 100 receives from an external source. The support block 300 may include bulk silicon. However, the inventive concept is not limited thereto. The support block 300 may be formed of various materials depending on the light that the first chip 100 receives. For example, the support block 300 may transmit light having a wavelength of 700 nm to 1500 nm.

The support block 300 may have a third insulating layer 310 provided on a lower surface of the support block 300 and a fourth insulating layer 320 provided on an upper surface of the support block 300. For example, the semiconductor package may further include a third insulating layer 310 provided on a lower surface of the support block 300 and a fourth insulating layer 320 provided on an upper surface of the support block 300.

Referring to FIGS. 1 and 2, the third insulating layer 310 may cover the lower surface of the support block 300. A thickness T1 of the third insulating layer 310 may be 1 nm to 100 nm. The third insulating layer 310 may include an oxide of a material constituting the support block 300, a nitride of the material constituting the support block 300, or an oxynitride of the material constituting the support block 300. The third insulating layer 310 may include, for example, at least one of silicon oxide (SiO), silicon nitride (SiN), and silicon oxynitride (SiON). As an example, the third insulating layer 310 may be a layer formed by performing an oxidation process, a nitridation process, or an oxy-nitridation process on the lower surface of the support block 300. Alternatively, as an example, the third insulating layer 310 may be a layer formed when the lower surface or the lower portion of the support block 300 is naturally oxidized, nitrided, or oxynitrided. The third insulating layer 310 may include the same material (e.g., the same first material) as the first insulating layer 122. Alternatively, the third insulating layer 310 and the first insulating layer 122 may include oxide, nitride, or oxynitride of the same material, but the third insulating layer 310 and the first insulating layer 122 may include different materials.

Referring to FIG. 1 and FIG. 3, the fourth insulating layer 320 may cover the upper surface of the support block 300. A thickness T2 of the fourth insulating layer 320 may be 1 nm to 100 nm. The fourth insulating layer 320 may include oxide of the material that constitutes the support block 300, nitride of the material that constitutes the support block 300, or oxynitride of the material that constitutes the support block 300. The fourth insulating layer 320 may include, for example, at least one of silicon oxide (SiO), silicon nitride (SiN), and silicon oxynitride (SiON). For example, the fourth insulating layer 320 may be a layer formed by performing an oxidation process, a nitriding process, or an oxidizing-nitriding process on the upper surface of the support block 300. Alternatively, for example, the fourth insulating layer 320 may be a layer formed when the upper surface or the upper portion of the support block 300 is naturally oxidized.

For convenience of explanation, a remaining portion of the support block 300 where the third and fourth insulating layers 310 and 320 are not formed is referred to as a light-transmitting layer 301 (e.g., a transparent layer). However, the name of the light-transmitting layer 301 does not limit the shape and material of each portion of the support block 300. Widths of the third and fourth insulating layers 310 and 320 may be the same as a width of the light-transmitting layer 301. Side surfaces of the third and fourth insulating layers 310 and 320 may be coplanar with side surfaces of the light-transmitting layer 301.

As an example, the third and fourth insulating layers 310 and 320 may be formed of silicon oxide (SiO), silicon nitride (SiN), or silicon oxynitride (SiON), and the light-transmitting layer 301 may be formed of silicon (Si). FIGS. 2 and 3 illustrate that the third and fourth insulating layers 310 and 320 include oxygen or nitrogen, but a concentration of oxygen or nitrogen in the third and fourth insulating layers 310 and 320 is not limited. For example, the concentration of oxygen or nitrogen in the third and fourth insulating layers 310 and 320 may be uniform. According to other embodiments, as shown in FIGS. 4 and 5, the concentration of oxygen or nitrogen in the third and fourth insulating layers 310 and 320 may gradually decrease from the lower surface or the upper surface of the support block 300 toward the light-transmitting layer 301 (e.g., toward the center of the support block 300).

Referring again to FIGS. 1 and 2, the support block 300 may be disposed on the first chip 100 in the second region R2. The lower surface of the support block 300 may be in contact with the upper surface of the first chip 100. Specifically, the lower surface of the third insulating layer 310 of the support block 300 may be in contact with the upper surface of the first insulating layer 122 of the first chip 100.

On an interface between the first chip 100 and the support block 300, the first insulating layer 122 of the first chip 100 and the third insulating layer 310 of the support block 300 may be bonded. In this case, the first insulating layer 122 and the third insulating layer 310 may form hybrid bonding of oxide, nitride, or oxynitride. In this specification, hybrid bonding means a combination in which two components including the same material are fused at their interface. For example, the first insulating layer 122 and the third insulating layer 310 bonded to each other may have an integral body, and the interface between the first insulating layer 122 and the third insulating layer 310 may not be visible or present. For example, the first insulating layer 122 and the third insulating layer 310 may be formed of the same material (e.g., silicon oxide (SiO) etc.), and thus an interface between the first insulating layer 122 and the third insulating layer 310 may not be visible or present. That is, the first insulating layer 122 and the third insulating layer 310 may be provided as a single, continuous component. For example, the first insulating layer 122 and the third insulating layer 310 may be combined to form an integral body. In the case of the embodiment of FIG. 4, a concentration of oxygen or nitrogen in the first insulating layer 122 and the third insulating layer 310 may gradually decrease from the first insulating layer 122 toward the light-transmitting layer 301.

According to embodiments of the inventive concept, a portion of the light-transmitting layer 301 that is disposed at a lower portion of the support block 300 may be oxidized or nitrided to form the third insulating layer 310, and the third insulating layer 310 may be combined with the first insulating layer 122 to form an integral body. Accordingly, the support block 300 may be firmly attached or combined to the first chip 100, and a semiconductor package with improved structural stability may be provided.

In addition, as the light-transmitting layer 301 is combined to the first chip 100 without using a separate adhesive material, the number of material layers through which light passes may be reduced in a path L of light that passes through the light-transmitting layer 301 and is incident on the sensor 112 of the first chip 100. Furthermore, as an interior of the support block 300, excluding the third and fourth insulating layers 310 and 320, that is, the light-transmitting layer 301, is formed of one material layer, it may be formed of a material having high transmittance for light to be received by the first chip 100, and light loss may be reduced. That is, the semiconductor package with improved optical characteristics may be provided.

Continuing with reference to FIG. 1, a microlens layer 400 may be provided on the support block 300. The microlens layer 400 may have a microlens ML formed on an upper surface of the microlens layer 400. For example, as illustrated in FIG. 1, the microlens ML may be provided in a form of a recess on the upper surface of the microlens layer 400. The microlens ML may be a spherical or otherwise curved surface whose bottom surface is convex upward. Alternatively, the microlens ML may have a shape of a spherical lens protruding upward from the upper surface of the microlens layer 400. Alternatively, the microlens ML may be provided in various shapes to the microlens layer 400 as needed. The microlens layer 400 may transmit light that the first chip 100 receives. The microlens layer 400 may include silicon (Si), glass, or various transparent materials. However, the inventive concept is not limited thereto. The microlens layer 400 may be formed of various materials depending on a wavelength of the light that the first chip 100 receives. For example, the microlens layer 400 may transmit light having a wavelength of 700 nm to 1500 nm.

The microlens layer 400 may have a fifth insulating layer 410 provided on a lower surface of the microlens layer 400. For example, the semiconductor package may further include a fifth insulating layer 410 provided on a lower surface of the microlens layer 400.

Referring to FIGS. 1 and 3, the fifth insulating layer 410 may cover the lower surface of the microlens layer 400. A thickness T3 of the fifth insulating layer 410 may be 1 nm to 100 nm. The fifth insulating layer 410 may include an oxide of a material constituting the microlens layer 400, a nitride of the material constituting the microlens layer 400, or an oxynitride of the material constituting the microlens layer 400. The fifth insulating layer 410 may include, for example, at least one of silicon oxide (SiO), silicon nitride (SiN), and silicon oxynitride (SiON). As an example, the fifth insulating layer 410 may be a layer formed by performing an oxidation process, a nitridation process, or an oxy-nitridation process on the lower surface of the microlens layer 400. Alternatively, as an example, the fifth insulating layer 410 may be a layer formed when the lower surface or the lower portion of the microlens layer 400 is naturally oxidized, nitrided, or oxynitrided. The fifth insulating layer 410 may include the same material (e.g., the same second material) as the fourth insulating layer 320. Alternatively, the fifth insulating layer 410 and the fourth insulating layer 320 may include oxide, nitride, or oxynitride of the same material, but the fifth insulating layer 410 and the fourth insulating layer 320 may include different materials.

As an example, the fifth insulating layer 410 may be formed of silicon oxide (SiO), silicon nitride (SiN), or silicon oxynitride (SiON), and a remaining portion of the microlens layer 400 may be formed of silicon (Si). FIG. 3 illustrates that the fifth insulating layer 410 includes oxygen or nitrogen, but a concentration of oxygen or nitrogen in the fifth insulating layer 410 is not limited. For example, the concentration of oxygen or nitrogen in the fifth insulating layer 410 may be uniform.

According to other embodiments, as illustrated in FIG. 5, the concentration of oxygen or nitrogen in the fifth insulating layer 410 may gradually decrease with distance away from the lower surface of the microlens layer 400.

Referring again to FIG. 1 and FIG. 3, the microlens layer 400 may be disposed on the support block 300. The lower surface of the microlens layer 400 may be in contact with the upper surface of the support block 300. Specifically, the lower surface of the fifth insulating layer 410 of the microlens layer 400 may be in contact with the upper surface of the fourth insulating layer 320 of the support block 300.

On an interface between the support block 300 and the microlens layer 400, the fourth insulating layer 320 of the support block 300 and the fifth insulating layer 410 of the microlens layer 400 may be bonded. In this case, the fourth insulating layer 320 and the fifth insulating layer 410 may form a hybrid bonding of oxide, nitride, or oxynitride. For example, the fourth insulating layer 320 and the fifth insulating layer 410 bonded to each other may have an integral body, and the interface between the fourth insulating layer 320 and the fifth insulating layer 410 may not be visible or present. For example, the fourth insulating layer 320 and the fifth insulating layer 410 may be formed of the same, continuous material (e.g., silicon oxide (SiO), etc.), and an interface between the fourth insulating layer 320 and the fifth insulating layer 410 may not be visible or present. That is, the fourth insulating layer 320 and the fifth insulating layer 410 may be provided as a single component. For example, the fourth insulating layer 320 and the fifth insulating layer 410 may be combined to form an integral body. In the case of the embodiment of FIG. 5, a concentration of oxygen or nitrogen in the fourth insulating layer 320 and the fifth insulating layer 410 may gradually decrease from the fourth insulating layer 320 toward the light-transmitting layer 301 and from the fifth insulating layer 410 toward the inside of the microlens layer 400.

According to embodiments of the inventive concept, the fourth insulating layer 320 formed by oxidizing or nitriding a portion of a light-transmitting layer 301 may be provided on the upper surface of the support block 300, and the fifth insulating layer 410 formed by oxidizing or nitriding the portion of the microlens layer 400 may be provided on the lower surface of the microlens layer 400. The fourth insulating layer 320 and the fifth insulating layer 410 may be combined with each other to form the integral body. Accordingly, the microlens layer 400 may be firmly attached or combined to the support block 300, and the semiconductor package with improved structural stability may be provided.

In addition, as the microlens layer 400 is combined to the support block 300 without using a separate adhesive member, the number of material layers through which light passes in the path L of light incident on the microlens layer 400 and passing through the support block 300 may be reduced. That is, the semiconductor package with improved optical characteristics may be provided.

Continuing with reference to FIG. 1, the upper surface of the microlens layer 400 may be positioned at the same level as the upper surface of the second chip 200.

A first molding layer 500 may be provided on the first chip 100. The first molding layer 500 may surround the second chip 200, the support block 300, and the microlens layer 400 on the first chip 100. The second chip 200 and the microlens layer 400 may be exposed on an upper surface of the first molding layer 500. The upper surface of the second chip 200 and the upper surface of the microlens layer 400 may form a coplanar surface with the upper surface of the first molding layer 500. The first molding layer 500 may include an insulating material. For example, the first molding layer 500 may include an insulating polymer material such as an epoxy molding compound (EMC).

In the following embodiments, for the convenience of explanation, detailed descriptions of technical features that overlap with those described above with reference to FIGS. 1 to 5 will be omitted, and differences will be described in detail. The same reference numerals may be provided for the same configurations as the semiconductor package according to the embodiments of the inventive concept described above.

FIG. 6 is a cross-sectional view for illustrating a semiconductor package according to embodiments of the inventive concept.

Referring to FIG. 6, the support block 300 may further include a sixth insulating layer 330 provided on the side surfaces of the support block 300.

The sixth insulating layer 330 may cover the side surfaces of the support block 300. A thickness T1 of the sixth insulating layer 330 may be 1 nm to 100 nm. The sixth insulating layer 330 may include an oxide of the material that constitutes the support block 300, a nitride of the material that constitutes the support block 300, or an oxynitride of the material that constitutes the support block 300. The sixth insulating layer 330 may include, for example, at least one of silicon oxide (SiO), silicon nitride (SiN), and silicon oxynitride (SiON). As an example, the sixth insulating layer 330 may be a layer formed by performing an oxidation process, a nitridation process, or an oxy-nitridation process on the side surfaces of the support block 300. Alternatively, as an example, the sixth insulating layer 330 may be a layer formed by naturally oxidizing, nitriding, or oxynitriding the side surfaces or sides of the support block 300.

The sixth insulating layer 330 may extend toward the lower surface of the support block 300 and may be connected to the third insulating layer 310. The sixth insulating layer 330 may extend toward the upper surface of the support block 300 and may be connected to the fourth insulating layer 320. The third insulating layer 310, the fourth insulating layer 320, and the sixth insulating layer 330 may be connected to each other to form a single, continuous layer. That is, the support block 300 may have a form in which the outer surfaces of the light-transmitting layer 301 are covered by layers formed of the third insulating layer 310, the fourth insulating layer 320, and the sixth insulating layer 330.

As an example, the sixth insulating layer 330 may be formed of silicon oxide (SiO), silicon nitride (SiN), or silicon oxynitride (SiON), and the light-transmitting layer 301 may be formed of silicon (Si). A concentration of oxygen or nitrogen in the sixth insulating layer 330 is not limited. For example, the concentration of oxygen or nitrogen in the sixth insulating layer 330 may be uniform.

According to other embodiments, the concentration of oxygen or nitrogen in the sixth insulating layer 330 may gradually decrease from the side surfaces of the support block 300 toward the light-transmitting layer 301 (e.g., toward the center of the support block 300).

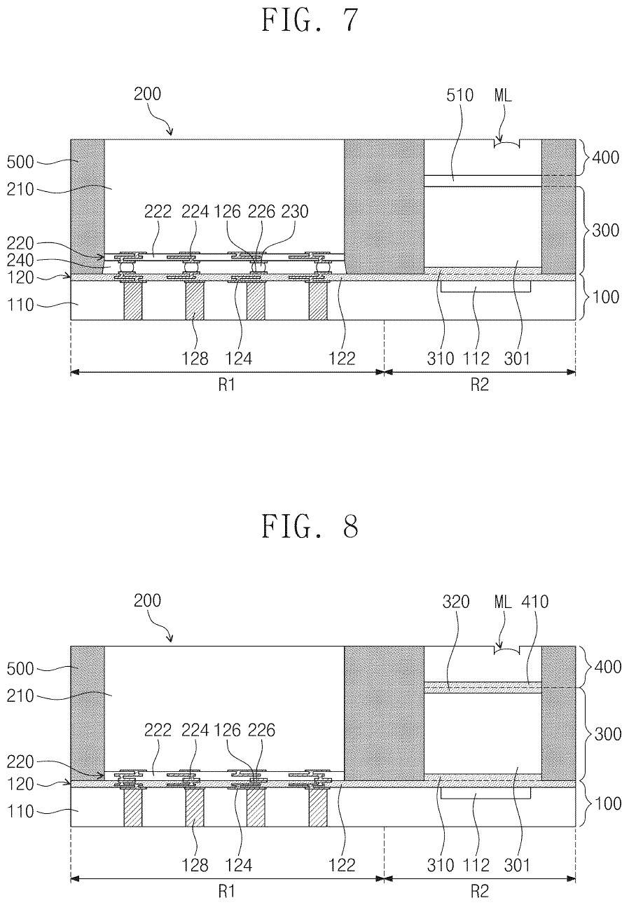

FIG. 7 is a cross-sectional view for illustrating a semiconductor package according to embodiments of the inventive concept.

Referring to FIG. 7, unlike the embodiments of FIGS. 1 to 6, the support block 300 may not include the fourth insulating layer 320. That is, an upper surface of the light- transmitting layer 301 of the support block 300 may be exposed. In addition, the microlens layer 400 may not include the fifth insulating layer 410.

The lower surface of the microlens layer 400 and the upper surface of the light-transmitting layer 301 may face each other.

An adhesive layer 510 may be interposed between the support block 300 and the microlens layer 400. The adhesive layer 510 may be adhered to the upper surface of the light-transmitting layer 301 and the lower surface of the microlens layer 400. The microlens layer 400 may be attached to the upper surface of the support block 300 using the adhesive layer 510. To transmit light incident through the microlens ML of the microlens layer 400 to the sensor 112 of the first chip 100, the adhesive layer 510 may include a transparent material. For example, the adhesive layer 510 may include an optical glue.

FIG. 8 is a cross-sectional view illustrating a semiconductor package according to embodiments of the inventive concept.

Referring to FIG. 8, the second chip 200 may be bonded to the first chip 100.

The first chip 100 may have first chip pads 126. The upper surface of the first chip pads 126 may be coplanar with the upper surface of the first insulating layer 122.

The second chip 200 may have second chip pads 226. The lower surface of the second chip pads 226 may be coplanar with the lower surface of the second insulating layer 222.

The second chip 200 may be mounted on the first chip 100. The lower surface of the second chip 200 may be in contact with the upper surface of the first chip 100. On the interface between the first chip 100 and the second chip 200, the first chip pads 126 and the second chip pads 226 may be bonded. In this case, the first chip pads 126 and the second chip pads 226 may form hybrid bonding between metals. For example, the first chip pads 126 and the second chip pads 226 bonded to each other may have an integral body, and an interface between the first chip pads 126 and the second chip pads 226 may not be visible or present. For example, the first chip pads 126 and the second chip pads 226 may be formed of the same material (e.g., copper (Cu) etc.), and an interface between the first chip pads 126 and the second chip pads 226 may not be visible or present. That is, the first chip pads 126 and the second chip pads 226 may be provided as a single component. For example, the first chip pads 126 and the second chip pads 226 may be combined to form an integral body. On the interface between the first chip 100 and the second chip 200, the first insulating layer 122 and the second insulating layer 222 may come into contact with each other.

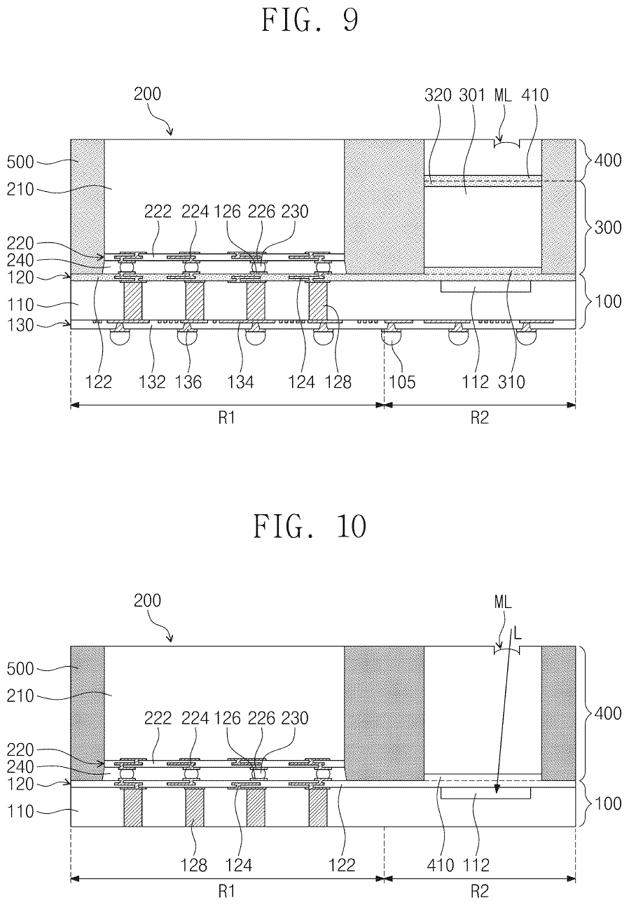

FIG. 9 is a cross-sectional view for illustrating a semiconductor package according to embodiments of the inventive concept.

Referring to FIG. 9, the first chip 100 may further include a wiring layer 130 provided on an inactive surface of the first chip 100. The wiring layer 130 may include a sixth insulating layer 132 and a third element wiring portion 134.

The lower surface of the first semiconductor substrate 110 may be covered with the sixth insulating layer 132. The sixth insulating layer 132 may cover the lower surface of the first semiconductor substrate 110. The sixth insulating layer 132 may include an oxide of a material constituting the first semiconductor substrate 110, a nitride of the material constituting the first semiconductor substrate 110, or an oxynitride of the material constituting the first semiconductor substrate 110. The sixth insulating layer 132 may include, for example, at least one of silicon oxide (SiO), silicon nitride (SiN), and silicon oxynitride (SiON).

The third element wiring portion 134 connected to the chip vias 128 may be provided in the sixth insulating layer 132. The third element wiring portion 134 may include wiring patterns embedded in the sixth insulating layer 132. For example, the wiring patterns may include redistribution patterns for horizontal wiring and via patterns for vertical connection. The third element wiring portion 134 may vertically penetrate the sixth insulating layer 132 and be connected to the chip vias 128. The third element wiring portion 134 may be disposed between the upper surface and the lower surface of the sixth insulating layer 132. The third element wiring portion 134 may include, for example, copper (Cu) or tungsten (W).

Third chip pads 136 may be provided on the lower surface of the sixth insulating layer 132. The third chip pads 136 may be exposed on the lower surface of the sixth insulating layer 132. The third chip pads 136 may protrude from the lower surface of the sixth insulating layer 132. Alternatively, the lower surface of the third chip pads 136 may be coplanar with the lower surface of the sixth insulating layer 132. The third chip pads 136 may be connected to the third element wiring portion 134. The third chip pads 136 may include, for example, copper (Cu) or tungsten (W).

Connection terminals 105 may be provided on the lower surface of the wiring layer 130. The connection terminals 105 may be connected to third chip pads 136. The connection terminals 105 may include solder balls or solder bumps, and depending on the type and arrangement of the connection terminals 105, the semiconductor package may be provided in a form of a ball grid array (BGA), a fine ball-grid array (FBGA), or a land grid array (LGA).

FIG. 10 is a cross-sectional view illustrating a semiconductor package according to embodiments of the inventive concept.

Referring to FIG. 10, a semiconductor package may not have a support block.

A microlens layer 400 may be provided on the first chip 100. The microlens layer 400 may be disposed on the second region R2. The microlens layer 400 may be disposed horizontally apart from the second chip 200. The microlens layer 400 may be disposed on the sensor 112. The microlens layer 400 may cover the entire sensor 112. The upper surface of the microlens layer 400 may be positioned at the same vertical level as the upper surface of the second chip 200. The microlens layer 400 may transmit light that the first chip 100 receives from an external source. The microlens layer 400 may have a fifth insulating layer 410 provided on the lower surface of the microlens layer 400. For example, the semiconductor package may further include a fifth insulating layer 410 provided on the lower surface of the microlens layer 400.

The microlens layer 400 may be disposed on the first chip 100 on the second region R2. The lower surface of the microlens layer 400 may be in contact with the upper surface of the first chip 100. Specifically, the lower surface of the fifth insulating layer 410 of the microlens layer 400 may be in contact with the upper surface of the first insulating layer 122 of the first chip 100.

On the interface between the first chip 100 and the microlens layer 400, the first insulating layer 122 of the first chip 100 and the fifth insulating layer 410 of the microlens layer 400 may be bonded. In this case, the first insulating layer 122 and the fifth insulating layer 410 may form a hybrid bonding of oxide, nitride, or oxynitride. For example, the first insulating layer 122 and the fifth insulating layer 410 bonded to each other may have an integral body, and an interface between the first insulating layer 122 and the fifth insulating layer 410 may not be visible or present. For example, the first insulating layer 122 and the fifth insulating layer 410 may be formed of the same, continuous material (e.g., silicon oxide (SiO) etc.), and an interface between the first insulating layer 122 and the fifth insulating layer 410 may not be visible or present. That is, the first insulating layer 122 and the fifth insulating layer 410 may be provided as a single component. For example, the first insulating layer 122 and the fifth insulating layer 410 may be combined to form an integral body.

According to embodiments of the inventive concept, the microlens layer 400 may be bonded onto the first chip 100, and further, the microlens layer 400 may be combined to the first chip 100 without using a separate adhesive material, and thus the number of material layers through which light passes may be reduced in the path L of light passing through the microlens layer 400 toward the first chip 100. That is, a semiconductor package with improved optical characteristics may be provided.

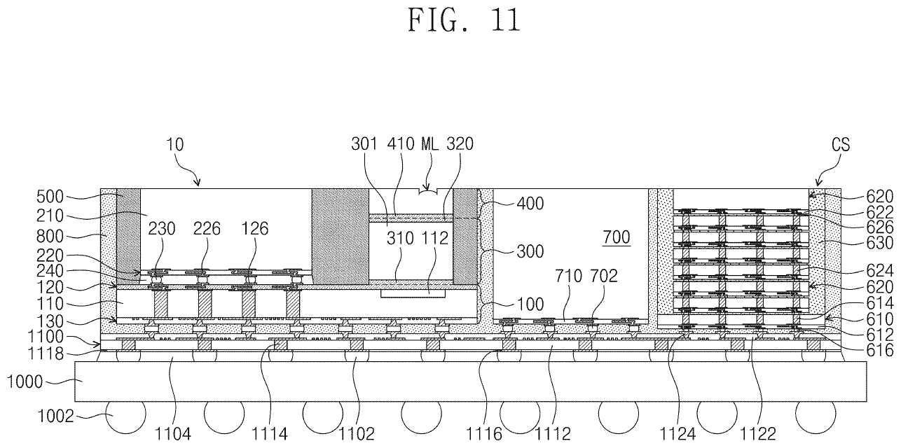

FIG. 11 is a cross-sectional view for illustrating a semiconductor package according to embodiments of the inventive concept.

Referring to FIG. 11, a package substrate 1000 may be provided. The package substrate 1000 may include a printed circuit board (PCB) having a signal pattern on an upper surface thereof. Alternatively, the package substrate 1000 may have a structure in which an insulating layer and a wiring layer are alternately stacked. The package substrate 1000 may have pads disposed on an upper surface thereof.

External terminals 1002 may be disposed under the package substrate 1000. Specifically, the external terminals 1002 may be disposed on terminal pads disposed on a lower surface of the package substrate 1000. The external terminals 1002 may include solder balls or solder bumps, and depending on the type and arrangement of the external terminals 1002, the semiconductor package may be provided in a form of a ball grid array (BGA), a fine ball-grid array (FBGA), or a land grid array (LGA).

An interposer substrate 1100 may be provided on the package substrate 1000. The interposer substrate 1100 may be a silicon (Si) interposer substrate. For example, the interposer substrate 1100 may include a silicon layer 1112, interposer vias 1114 vertically penetrating the silicon layer 1112, interposer lower pads 1116 provided on a lower surface of the silicon layer 1112 and connected to the interposer vias 1114, an interposer passivation layer 1118 provided on a lower surface of the silicon layer 1112 and surrounding the interposer lower pads 1116, and an interposer wiring portion provided on an upper surface of the silicon layer 1112.

The silicon layer 1112 may be a silicon (Si) substrate. The interposer vias 1114 may completely penetrate the silicon layer 1112 vertically. That is, the upper surface of the interposer vias 1114 may be exposed on the upper surface of the silicon layer 1112, and the lower surface of the interposer vias 1114 may be exposed on the lower surface of the silicon layer 1112. The interposer vias 1114 may include a metal such as copper (Cu).

The interposer lower pads 1116 may be disposed on the lower surface of the interposer vias 1114 on the lower surface of the silicon layer 1112. The interposer lower pads 1116 may include a metal such as copper (Cu).

The interposer passivation layer 1118 may be disposed on a lower surface of a silicon layer 1112. The interposer passivation layer 1118 may expose lower surfaces of interposer lower pads 1116. The interposer passivation layer 1118 may include a photoimageable dielectric (PID). For example, the photoimageable dielectric may include at least one of a photoimageable polyimide, a polybenzoxazole (PBO), a phenol-based polymer, or a benzocyclobutene-based polymer.

The interposer wiring portion may include at least one substrate wiring layer. Each of the substrate wiring layers may include a first substrate insulating pattern 1122 and a first substrate wiring pattern 1124 in the first substrate insulating pattern 1122. The first substrate wiring pattern 1124 may be electrically connected to the interposer vias 1114. The first substrate insulating pattern 1122 may include an insulating polymer or a photoimageable dielectric (PID). The first substrate wiring pattern 1124 may be provided in the first substrate insulating pattern 1122. The first substrate wiring pattern 1124 may have a damascene structure. For example, the first substrate wiring pattern 1124 may have a head portion and a tail portion that are integrally connected to each other. The head portion may be a wiring portion or a pad portion that horizontally extends wiring in the substrate wiring layers. The tail portion may be a via portion that vertically connects wiring in the substrate wiring layers. The first substrate wiring pattern 1124 may include a conductive material. For example, the first substrate wiring pattern 1124 may include copper (Cu).

The head portion of the first substrate wiring pattern 1124 of the substrate wiring layer disposed at the uppermost end among the substrate wiring layers may correspond to (e.g., may function as) the interposer upper pads of the interposer substrate 1100. The substrate pads may be substrate pads for mounting a first chip structure 10 and a second chip structure CS or 700.

Unlike that illustrated in FIG. 11, the interposer substrate 1100 may be a redistribution substrate. For example, the interposer substrate 1100 may include at least two substrate wiring layers. Each of the substrate wiring layers may include a substrate insulation pattern and a substrate wiring pattern in the substrate insulation pattern. The substrate wiring pattern of one substrate wiring layer may be electrically connected to the substrate wiring pattern of another adjacent substrate wiring layer. Hereinafter, the description will continue based on the embodiment of FIG. 11.

The interposer substrate 1100 may be mounted on the upper surface of the package substrate 1000. Substrate terminals 1102 may be disposed on a lower surface of the interposer substrate 1100. The substrate terminals 1102 may be provided between the pads of the package substrate 1000 and the interposer lower pads 1116 of the interposer substrate 1100. The substrate terminals 1102 may electrically connect the interposer substrate 1100 to the package substrate 1000. For example, the interposer substrate 1100 may be mounted on the package substrate 1000 in a flip chip manner. The substrate terminals 1102 may include solder balls or solder bumps, etc.

A first underfill layer 1104 may be provided between the package substrate 1000 and the interposer substrate 1100. The first underfill layer 1104 may fill a space between the package substrate 1000 and the interposer substrate 1100 and surround the substrate terminals 1102.

A first chip structure 10 may be disposed on the interposer substrate 1100. The first chip structure 10 may be a semiconductor package described with reference to FIGS. 1 to 10.

The first chip structure 10 may be mounted on the interposer substrate 1100. For example, the first chip structure 10 may be connected to the first substrate wiring pattern 1124 of the interposer substrate 1100 through the connection terminals 105 of the first chip 100 (see, e.g., FIG. 9). The connection terminals 105 may be provided between the first substrate wiring pattern 1124 of the interposer substrate 1100 and the wiring layer 130 of the first chip 100.

Although not illustrated, an underfill layer may be provided between the interposer substrate 1100 and the first chip structure 10. The underfill layer may fill a space between the interposer substrate 1100 and the first chip 100 and surround the connection terminals 105.

A second chip structure may be disposed on the interposer substrate 1100. The second chip structure may be disposed to be horizontally spaced apart from the first chip structure 10. The second chip structure may include a chip stack CS and a fourth semiconductor chip 700.

The chip stack CS may include a base substrate, third semiconductor chips 620 stacked on the base substrate, and a second molding layer 630 surrounding the third semiconductor chips 620. Hereinafter, the configuration of the chip stack CS will be described in detail.

The base substrate may be a base semiconductor chip 610. For example, the base substrate may be a wafer-level semiconductor substrate formed of a semiconductor such as silicon (Si). Hereinafter, the base semiconductor chip 610 refers to the same component as the base substrate, and the same reference numerals for the base semiconductor chip and the base substrate may be used.

The base semiconductor chip 610 may include a base circuit layer 612 and base penetration electrodes 614. The base circuit layer 612 may be provided on a lower surface of the base semiconductor chip 610. The base circuit layer 612 may include an integrated circuit. For example, the base circuit layer 612 may be a memory circuit. That is, the base semiconductor chip 610 may be a memory chip such as DRAM, SRAM, MRAM, or flash memory. The base penetration electrodes 614 may penetrate the base semiconductor chip 610 in a direction perpendicular to the upper surface of the interposer substrate 1100. The base penetration electrodes 614 and the base circuit layer 612 may be electrically connected to each other. A lower surface of the base semiconductor chip 610 may be an active surface. Although FIG. 11 illustrates the base substrate includes the base semiconductor chip 610, the inventive concept is not limited thereto. According to embodiments of the inventive concept, the base substrate may not include the base semiconductor chip 610.

The base semiconductor chip 610 may further include a protective layer and base connection terminals 616. The protective layer may be disposed on a lower surface of the base semiconductor chip 610 to cover the base circuit layer 612. The protective layer may include silicon nitride (SiN). Base connection terminals 616 may be provided on the lower surface of the base semiconductor chip 610. The base connection terminals 616 may be electrically connected to an input/output circuit (i.e., the memory circuit), a power circuit, or a ground circuit of the base circuit layer 612. The base connection terminals 616 may be exposed from the protective layer.

The third semiconductor chip 620 may be mounted on the base semiconductor chip 610. That is, the third semiconductor chip 620 may form a chip on wafer (COW) structure with the base semiconductor chip 610. A horizontal width of the third semiconductor chip 620 may be smaller than a horizontal width of the base semiconductor chip 610.

The third semiconductor chip 620 may include a third circuit layer 622 and chip penetration electrodes 624. The third circuit layer 622 may include a memory circuit. That is, the third semiconductor chip 620 may be a memory chip such as a DRAM, an SRAM, an MRAM, or a flash memory. The third circuit layer 622 may include the same circuit as the base circuit layer 612, but the inventive concept is not limited thereto. The chip penetration electrodes 624 may penetrate the third semiconductor chip 620 in a direction perpendicular to an upper surface of the interposer substrate 1100. The chip penetration electrodes 624 and the third circuit layer 622 may be electrically connected to each other. A lower surface of the third semiconductor chip 620 may be an active surface. First chip bumps 626 may be provided on the lower surface of the third semiconductor chip 620. The first chip bumps 626 may electrically connect the base semiconductor chip 610 to the third semiconductor chip 620 and may be provided between the base semiconductor chip 610 and the third semiconductor chip 620.

The third semiconductor chip 620 may be provided in the plural. For example, a plurality of third semiconductor chips 620 may be stacked on the base semiconductor chip 610. For example, the third semiconductor chips 620 may be stacked in numbers of 4 to 32. The first chip bumps 626 may be provided between each of the third semiconductor chips 620. In this case, the uppermost third semiconductor chip 620 may not include chip penetration electrodes 624. In addition, a thickness of the uppermost third semiconductor chip 620 may be thicker than a thickness of the third semiconductor chips 620 disposed therebelow.

Although not illustrated, an adhesive layer may be provided between adjacent third semiconductor chips 620. The adhesive layer may include a non-conductive film (NCF). The adhesive layer may be interposed between the first chip bumps 626 between the third semiconductor chips 620, thereby preventing an electrical short between the first chip bumps 626.

A second molding layer 630 may be disposed on an upper surface of the base semiconductor chip 610. The second molding layer 630 may cover the base semiconductor chip 610 and surround the third semiconductor chips 620. An upper surface of the second molding layer 630 may be coplanar with an upper surface of the uppermost third semiconductor chip 620, and the uppermost third semiconductor chip 620 may be exposed from the second molding layer 630. The second molding layer 630 may include an insulating polymer material. For example, the second molding layer 630 may include an epoxy molding compound (EMC).

The chip stack CS may be mounted on the interposer substrate 1100. For example, the chip stack CS may be connected to the first substrate wiring pattern 1124 of the interposer substrate 1100 through the base connection terminals 616 of the base semiconductor chip 610. The base connection terminals 616 may be provided between the first substrate wiring pattern 1124 of the interposer substrate 1100 and the base circuit layer 612.

Although not shown, an underfill layer may be provided between the interposer

substrate 1100 and the chip stack CS. The underfill layer may fill a space between the interposer substrate 1100 and the base semiconductor chip 610 and may surround the base connection terminals 616.

A fourth semiconductor chip 700 may be disposed on the interposer substrate 1100. The fourth semiconductor chip 700 may be disposed spaced apart from the chip stack CS. A thickness of the fourth semiconductor chip 700 may be substantially the same as a thickness of the chip stack CS. The fourth semiconductor chip 700 may include a semiconductor material such as silicon (Si). The fourth semiconductor chip 700 may include a fourth circuit layer 710. The fourth circuit layer 710 may include a logic circuit. That is, the fourth semiconductor chip 700 may be a logic chip. For example, the fourth semiconductor chip 700 may be a system on chip (SOC). A lower surface of the fourth semiconductor chip 700 may be an active surface, and an upper surface of the fourth semiconductor chip 700 may be an inactive surface.

Second chip bumps 702 may be provided on the lower surface of the fourth semiconductor chip 700. The second chip bumps 702 may be electrically connected to an input/output circuit (i.e., the logic circuit), a power circuit, or a ground circuit of the fourth circuit layer 710.

The fourth semiconductor chip 700 may be mounted on an interposer substrate 1100. For example, the fourth semiconductor chip 700 may be connected to a first substrate wiring pattern 1124 of the interposer substrate 1100 through the second chip bumps 702. The second chip bumps 702 may be provided between the first substrate wiring pattern 1124 of the interposer substrate 1100 and the fourth circuit layer 710 of the fourth semiconductor chip 700.

Although not illustrated, an underfill layer may be provided between the interposer substrate 1100 and the fourth semiconductor chip 700. The underfill layer may fill a space between the interposer substrate 1100 and the fourth semiconductor chip 700 and may surround the second chip bumps 702.

A third molding layer 800 may be provided on the interposer substrate 1100. The third molding layer 800 may cover an upper surface of the interposer substrate 1100. The third molding layer 800 may surround the first chip structure 10 and the second chip structure CS or 700. The third molding layer 800 may expose an upper surface of the first chip structure 10, an upper surface of the chip stack CS, and an upper surface of the fourth semiconductor chip 700. For example, the third molding layer 800 may include an insulating material. For example, the third molding layer 800 may include an epoxy molding compound (EMC).

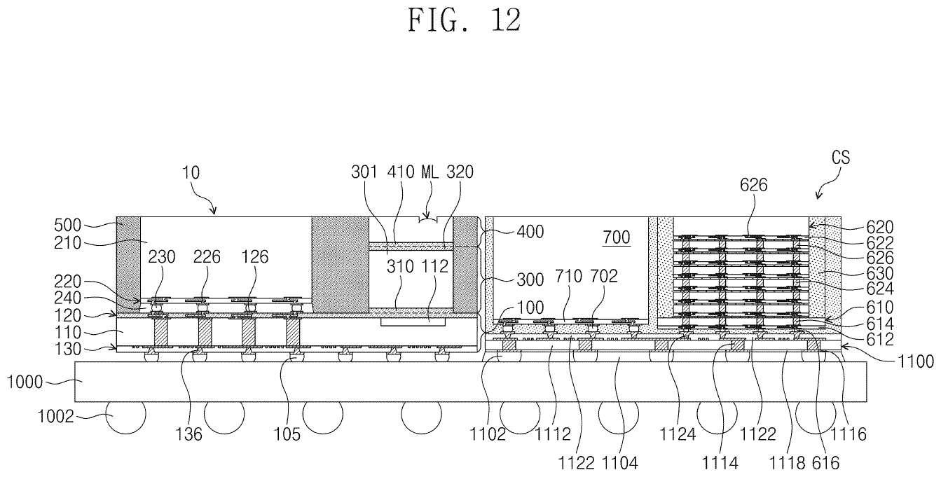

FIG. 12 is a cross-sectional view illustrating a semiconductor package according to embodiments of the inventive concept.

FIG. 11 illustrates the first chip structure 10 is mounted on an interposer substrate 1100, but the inventive concept is not limited thereto.

Referring to FIG. 12, the first chip structure 10 may be disposed on a package substrate 1000. The first chip structure 10 may be disposed horizontally spaced from the interposer substrate 1100. The first chip structure 10 may be mounted on an upper surface of the package substrate 1000. For example, the first chip structure 10 may be connected to the pads of the package substrate 1000 through the connection terminals 105 of the first chip 100. The connection terminals 105 may be provided between the pads of the package substrate 1000 and the wiring layer 130 of the first chip 100. The connection terminals 105 may electrically connect the first chip structure 10 to the package substrate 1000. For example, the first chip structure 10 may be mounted on the package substrate 1000 in a flip chip manner. For example, the connection terminals 105 may contact the pads of the package substrate 1000 and the wiring layer 130 of the first chip 100.

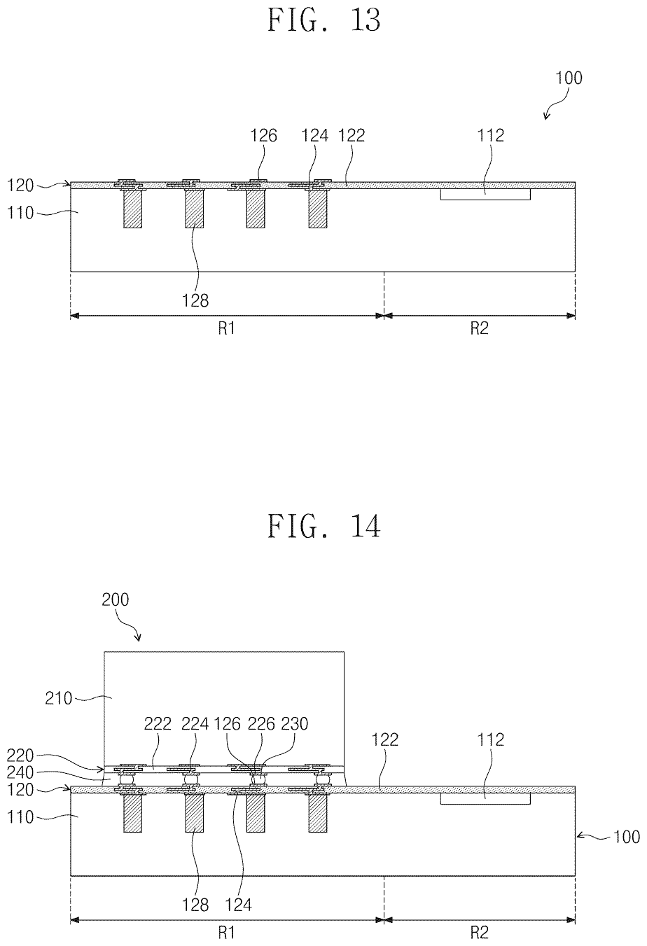

FIGS. 13 to 24 are cross-sectional views for illustrating a method of fabricating a semiconductor package according to embodiments of the inventive concept.

Referring to FIG. 13, a first chip 100 may be formed by performing a conventional process. For example, a first integrated element may be formed on an upper surface of a first semiconductor substrate 110. The first integrated element may include a photonic integrated circuit (PIC). A sensor 112 may be formed on the upper surface of the first semiconductor substrate 110 in a second region R2 of the first semiconductor substrate 110. The sensor 112 may be exposed on the upper surface of the first semiconductor substrate 110. On the first region R1 of the first semiconductor substrate 110, after forming holes on the upper surface of the first semiconductor substrate 110, a conductive material may be filled in the holes to form chip vias 128. Upper ends of the chip vias 128 may be exposed on the upper surface of the first semiconductor substrate 110. Lower ends of the chip vias 128 may be disposed inside the first semiconductor substrate 110. A first circuit layer 120 may be formed on the upper surface of the first semiconductor substrate 110. For example, an insulating layer covering the upper surface of the first semiconductor substrate 110 may be formed, and then the insulating layer may be patterned to form a first insulating layer 122. A conductive layer may be formed on the first insulating layer 122 and then the conductive layer may be patterned to form a first element wiring portion 124. The insulating layer and the conductive layer may be repeatedly deposited and patterned to form the first insulating layer 122 and the first element wiring portion 124.

Referring to FIG. 14, a second chip 200 may be provided. The second chip 200 may be substantially the same as or similar to the second chip 200 described with reference to FIGS. 1 to 10.

The second chip 200 may be mounted on the first chip 100. The second chip 200 may be mounted on the first chip 100 in a flip chip manner. First connection terminals 230 may be provided on a lower surface of the second chip 200. The first connection terminals 230 may include solder balls or solder bumps. A first underfill layer 240 may be provided on the lower surface of the second chip 200 to surround the first connection terminals 230. For example, a first underfill layer 240 may be a non-conductive adhesive or a non-conductive layer. When the first underfill layer 240 is a non-conductive adhesive, the first underfill layer 240 may be formed by applying (e.g., dispensing) a liquid non-conductive adhesive onto the lower surface of the second chip 200. When the first underfill layer 240 is a non-conductive layer, the first underfill layer 240 may be formed by attaching the non-conductive layer onto the lower surface of the second chip 200. Thereafter, the second chip 200 may be aligned so that the first connection terminals 230 are positioned on the first chip pads 126 of the first chip 100, and then a reflow process may be performed on the second chip 200.

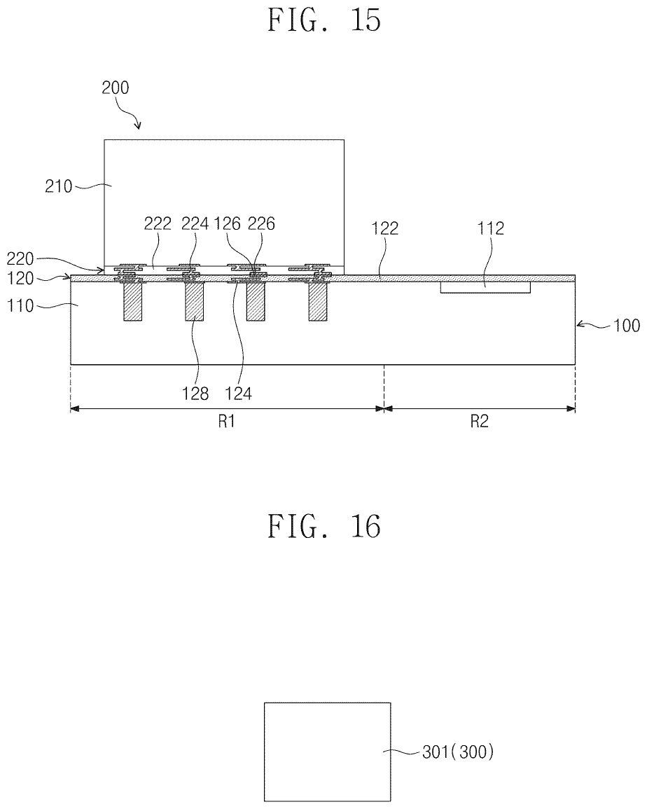

According to other embodiments, as shown in FIG. 15, the second chip 200 may be bonded on the first chip 100. The second chip 200 may be moved so that the lower surface of the second chip 200 comes into contact with the upper surface of the first chip 100. The second chip pads 226 of the second chip 200 may be aligned with the first chip pads 126 of the first chip 100. The second chip pads 226 and the first chip pads 126 may come into contact with each other. A heat treatment process may be performed on the first chip 100 and the second chip 200. The second chip pads 226 and the first chip pads 126 may be bonded by the heat treatment process. For example, the second chip pads 226 and the first chip pads 126 may be combined to form an integral body. The combination of the second chip pads 226 and the first chip pads 126 may naturally proceed. In detail, the second chip pads 226 and the first chip pads 126 may be formed of the same material (e.g., copper (Cu) etc.), and the second chip pads 226 and the first chip pads 126 may be combined to each other by a metal hybrid bonding process through surface activation at an interface between the second chip pads 226 and the first chip pads 126 that are in contact with each other. The second chip pads 226 and the first chip pads 126 may be bonded by the heat treatment process. Hereinafter, the description will continue based on the embodiment of FIG. 14.

Referring to FIG. 16, a support block 300 may be formed. The support block 300 may be a block formed of a single material. For example, the support block 300 may include bulk silicon (bulk Si). For convenience of explanation, a portion formed of the single material in the support block 300 is referred to as a light-transmitting layer 301.

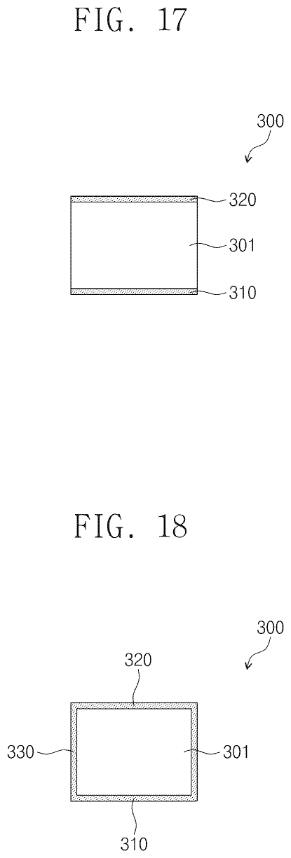

Referring to FIG. 17, a third insulating layer 310 and a fourth insulating layer 320 may be formed on a lower surface and an upper surface of the support block 300, respectively. For example, an oxidation process, a nitridation process, or an oxy-nitridation process may be performed on the lower surface and the upper surface of the support block 300 to form the third insulating layer 310 and the fourth insulating layer 320. Alternatively, the third insulating layer 310 and the fourth insulating layer 320 may be layers formed when the lower surface and the upper surface of the support block 300 are naturally oxidized. Accordingly, the support block 300 may be formed of a light-transmitting layer 301 formed of a single material, and the third insulating layer 310 and the fourth insulating layer 320 provided on the lower surface and upper surface of the light-transmitting layer 301 and formed of an oxide, nitride or oxynitride of the single material.

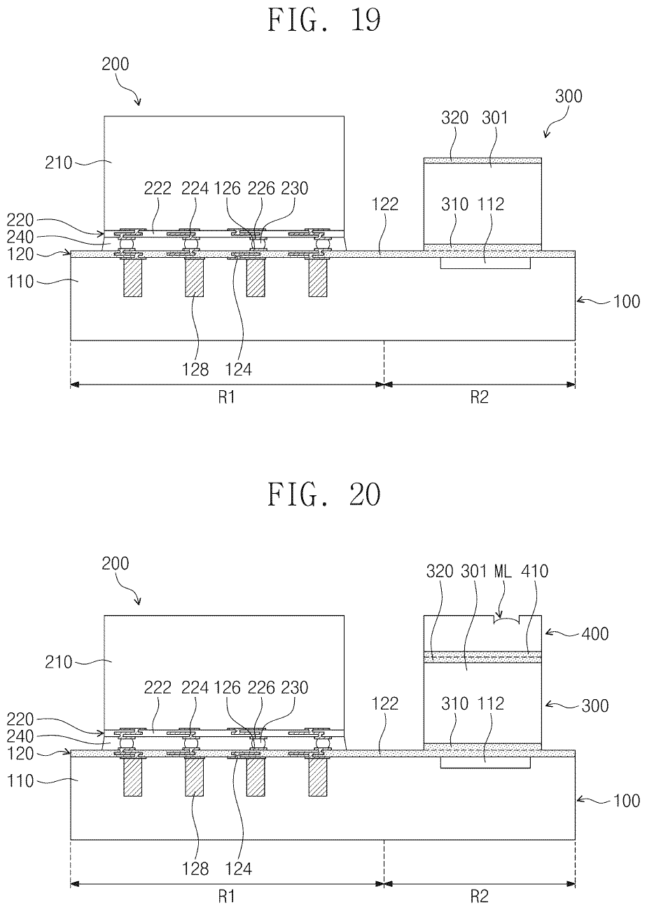

According to other embodiments, as shown in FIG. 18, the third insulating layer 310, the fourth insulating layer 320, and a sixth insulating layer 330 may be formed on the lower surface, the upper surface, and side surfaces of the support block 300. For example, an oxidation process, a nitridation process or an oxy-nitridation process may be performed on outer surfaces of the support block 300 to form the third insulating layer 310 and the fourth insulating layer 320. Alternatively, the third insulating layer 310 and the fourth insulating layer 320 may be layers formed when the outer surfaces of the support block 300 are naturally oxidized. Hereinafter, the description will continue based on the embodiment of FIG. 17.

Referring to FIG. 19, the support block 300 may be disposed on the first chip 100. The support block 300 may be disposed on the second region R2 of the first chip 100. The lower surface of the support block 300, that is, the lower surface of the third insulating layer 310, may be in contact with the first insulating layer 122 of the first chip 100. The third insulating layer 310 and the first insulating layer 122 may be bonded to each other. A heat treatment process may be performed on the third insulating layer 310 and the first insulating layer 122. The third insulating layer 310 and the first insulating layer 122 may be bonded by the heat treatment process. For example, the third insulating layer 310 and the first insulating layer 122 may be combined to form an integral body. The combination of the third insulating layer 310 and the first insulating layer 122 may occur naturally. Specifically, the third insulating layer 310 and the first insulating layer 122 may be formed of the same, continuous material (e.g., silicon oxide (SiO) etc.), and the third insulating layer 310 and the first insulating layer 122 may be combined by material diffusion in the oxide/nitride/oxynitride at an interface between the third insulating layer 310 and the first insulating layer 122 that are in contact with each other. The third insulating layer 310 and the first insulating layer 122 may be bonded by the heat treatment process.

Referring to FIG. 20, a microlens layer 400 may be provided. The microlens layer 400 may be substantially the same as or similar to the microlens layer 400 described with reference to FIGS. 1 to 10.

A fifth insulating layer 410 may be formed on the lower surface of the microlens layer 400. For example, an oxidation process, a nitridation process, or an oxy-nitridation process may be performed on the lower surface of the microlens layer 400. Alternatively, the fifth insulating layer 410 may be formed when the lower surface of the microlens layer 400 is naturally oxidized.

The microlens layer 400 may be disposed on the support block 300. A lower surface of the microlens layer 400, that is, a lower surface of the fifth insulating layer 410, may be in contact with a fourth insulating layer 320 of the support block 300. The fifth insulating layer 410 and the fourth insulating layer 320 may be bonded to each other. A heat treatment process may be performed on the fifth insulating layer 410 and the fourth insulating layer 320. The fifth insulating layer 410 and the fourth insulating layer 320 may be bonded by the heat treatment process. For example, the fifth insulating layer 410 and the fourth insulating layer 320 may be combined to form an integral body. The combination of the fifth insulating layer 410 and the fourth insulating layer 320 may proceed naturally. In detail, the fifth insulating layer 410 and the fourth insulating layer 320 may be formed of the same, continuous material (e.g., silicon oxide (SiO) etc.), and the fifth insulating layer 410 and the fourth insulating layer 320 may be combined by material diffusion in the oxide/nitride/oxynitride at an interface between the fifth insulating layer 410 and the fourth insulating layer 320 that are in contact with each other. The fifth insulating layer 410 and the fourth insulating layer 320 may be bonded by the heat treatment process.

FIGS. 19 and 20 illustrate that the support block 300 is bonded on the first chip 100, and then the microlens layer 400 is bonded on the support block 300, but the inventive concept is not limited thereto. According to other embodiments, before bonding the support block 300 onto the first chip 100, the support block 300 and the microlens layer 400 may be bonded to each other first. Specifically, the microlens layer 400 may be disposed on the fourth insulating layer 320 of the support block 300. The lower surface of the microlens layer 400, that is, the lower surface of the fifth insulating layer 410, may be in contact with the fourth insulating layer 320 of the support block 300. The fifth insulating layer 410 and the fourth insulating layer 320 may be bonded to each other. At the interface between the fifth insulating layer 410 and the fourth insulating layer 320 that are in contact with each other, the fifth insulating layer 410 and the fourth insulating layer 320 may be combined by material diffusion in the oxide/nitride/oxynitride. The support block 300 and the microlens layer 400 may be provided at a wafer level. For example, a plurality of support blocks 300 may be formed on one silicon substrate or silicon wafer. A plurality of microlens layers 400 may be formed on one silicon substrate or silicon wafer. The substrate of the support blocks 300 and the substrate of the microlens layers 400 may be bonded to each other. Afterwards, a cutting process may be performed on the substrates such that individual structures each including one support block 300 and one microlens layer 400 may be separated from each other.

The structure in which the support block 300 and the microlens layer 400 are bonded may be combined to the first chip 100. The structure may be disposed on the first chip 100. The structure may be disposed on the second region R2 of the first chip 100. A lower surface of the structure, that is, the lower surface of the third insulating layer 310, may be in contact with the first insulating layer 122 of the first chip 100. The third insulating layer 310 and the first insulating layer 122 may be bonded to each other. At the interface between the third insulating layer 310 and the first insulating layer 122 in contact with each other, the third insulating layer 310 and the first insulating layer 122 may be combined by material diffusion in the oxide/nitride/oxynitride. The third insulating layer 310 and the first insulating layer 122 may be bonded by a heat treatment process. Hereinafter, the description will continue based on the embodiment of FIG. 20.

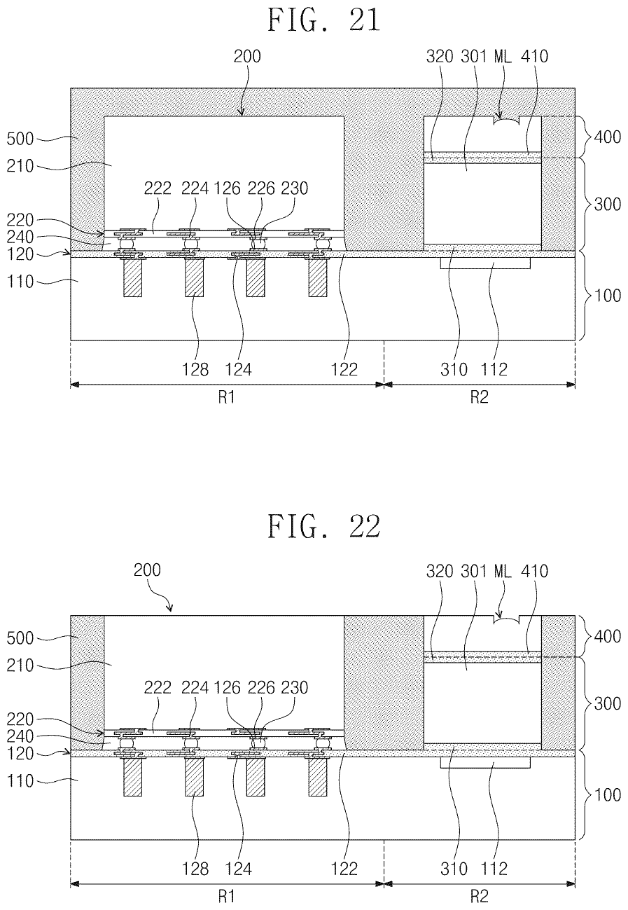

Referring to FIG. 21, a first molding layer 500 may be formed. For example, an insulating material may be applied on the first chip 100 to form the first molding layer 500. The first molding layer 500 may cover the second chip 200, the support block 300, and the microlens layer 400.

Referring to FIG. 22, a grinding process may be performed on the first molding layer 500. An upper portion of the first molding layer 500 may be removed so that the upper surface of the first molding layer 500 may be coplanar with the upper surface of the second chip 200 and the upper surface of the microlens layer 400.

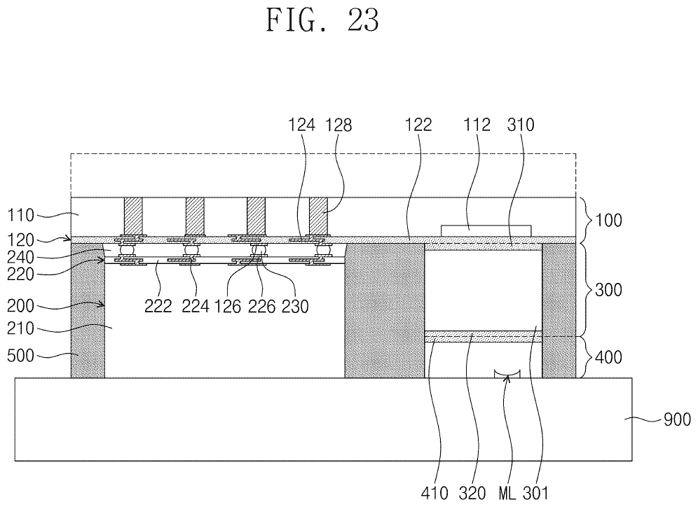

A carrier substrate 900 (see, e.g., FIG. 23) may be attached on the first molding layer 500. The carrier substrate 900 may be an insulating substrate including glass or polymer, or a conductive substrate including metal. Although not shown, an adhesive member may be provided on one surface of the carrier substrate 900 so that the first molding layer 500 may be attached to the carrier substrate 900. For example, the adhesive member may include an adhesive tape.

Referring to FIG. 23, the structure of FIG. 22 may be flipped over so that the first chip 100 is disposed on the carrier substrate 900.

A grinding process may be performed on the first chip 100. For example, the grinding process may be performed on the upper surface of the first semiconductor substrate 110 of the first chip 100. A portion of the upper surface of the first semiconductor substrate 110 may be removed. The grinding process may be performed until the upper surface of the chip vias 128 (e.g., as oriented in FIG. 23) is exposed. The upper surface of the first semiconductor substrate 110 may be coplanar with the upper surfaces of the chip vias 128.

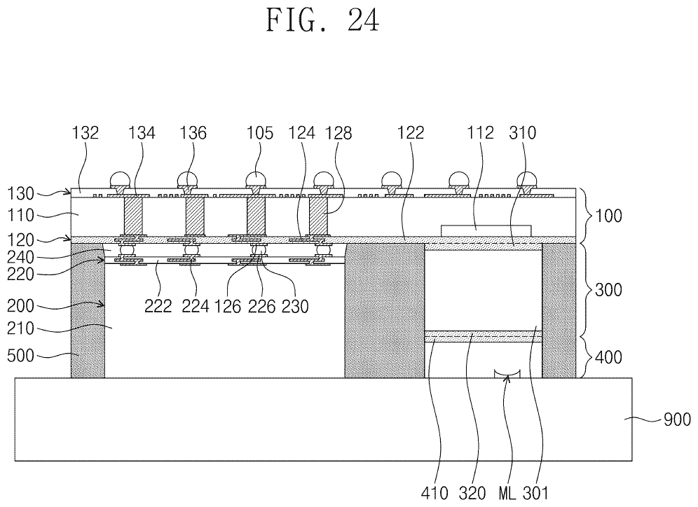

Referring to FIG. 24, a wiring layer 130 may be formed on the first semiconductor substrate 110. For example, an insulating layer covering the upper surface of the first semiconductor substrate 110 may be formed, and then the insulating layer may be patterned to form a sixth insulating layer 132. A conductive layer may be formed on the sixth insulating layer 132, and then a third element wiring portion 134 may be formed on the conductive layer. The insulating layer and the conductive layer may be repeatedly deposited and patterned to form the sixth insulating layer 132 and the third element wiring portion 134. Thereafter, the sixth insulating layer 132 may be patterned to form holes exposing the third element wiring portion 134, and then third chip pads 136 connected to the third element wiring portion 134 may be formed on the sixth insulating layer 132.

Connection terminals 105 may be provided on the third chip pads 136. The connection terminals 105 may be connected to the upper surface of the third chip pads 136.

Thereafter, the carrier substrate 900 may be removed.

According to embodiments of the inventive concept, the semiconductor package may be provided with the insulating layers formed by oxidizing or nitriding the portion of the light-transmitting layer on the lower and upper portions of the support block, and the insulating layers may be formed by the insulating layer of the first chip or the insulating of the microlens to be an integral body. Accordingly, the support block may be firmly attached or combined to the first chip, and the microlens layer may be firmly attached or combined to the support block. That is, the semiconductor package with the improved structural stability may be provided.

In addition, as the light-transmitting layer is combined to the first chip and the microlens layer without using a separate adhesive member, the number of material layers through which light passes may be small in the path of light that is incident on the microlens layer and passes through the light-transmitting layer and is incident on the sensor. Furthermore, as the interior of the support block, excluding the insulating layers, that is, the light-transmitting layer is formed of one material layer (e.g., a layer including a single material), the material having the high transmittance for light to be received by the first chip may be provided, and the light loss may be reduced. That is, the semiconductor package with the improved optical characteristics may be provided.

While embodiments are described above, a person skilled in the art may understand that many modifications and variations are made without departing from the spirit and scope of the inventive concept. Accordingly, the example embodiments of the inventive concept should be considered in all respects as illustrative and not restrictive.

1. A semiconductor package comprising:
a first substrate;
a first chip structure mounted on the first substrate; and
a first molding layer surrounding the first chip structure on the first substrate,
wherein the first chip structure includes:
a first chip on the first substrate, the first chip including a photonic integrated circuit (PIC);
a second chip on the first chip, the second chip including an electronic integrated circuit (EIC);
a transparent layer horizontally spaced from the second chip on the first chip;
a microlens layer on the transparent layer; and
a second molding layer surrounding the second chip, the transparent layer, and the microlens layer on the first chip,
wherein the semiconductor package further comprises a first insulating layer provided on an upper surface of the first chip,
wherein the semiconductor package further comprises a second insulating layer provided on a lower surface of the transparent layer, and
wherein the first insulating layer and the second insulating layer are in contact with each other, and the first insulating layer and the second insulating layer are integrally formed of the same first material.

2. The semiconductor package of claim 1, wherein an upper surface of the transparent layer is in contact with a lower surface of the microlens layer.

3. The semiconductor package of claim 2, wherein the semiconductor package further comprises a third insulating layer provided on the upper surface of the transparent layer,
wherein the semiconductor package further comprises a fourth insulating layer provided on the lower surface of the microlens layer, and
wherein the third insulating layer and the fourth insulating layer are in contact with each other, and the third insulating layer and the fourth insulating layer are integrally formed of the same second material.

4. The semiconductor package of claim 1, wherein the first chip further includes a sensor disposed below the transparent layer, and
wherein the sensor is configured to receive light that is incident on the microlens layer and transmitted through the transparent layer.

5. The semiconductor package of claim 1, wherein the transparent layer is configured to transmit light having a wavelength of 700 nm to 1500 nm.

6. The semiconductor package of claim 5, wherein the transparent layer includes silicon (Si).

7. The semiconductor package of claim 1, wherein a thickness of the second insulating layer is 1 nm to 100 nm.

8. The semiconductor package of claim 1, wherein the first insulating layer and the second insulating layer include an oxide of a material constituting the transparent layer, a nitride of the material constituting the transparent layer, or an oxynitride of the material constituting the transparent layer.

9. The semiconductor package of claim 1, wherein an upper surface of the second chip and an upper surface of the microlens layer are positioned at the same vertical level.

10. The semiconductor package of claim 1, wherein the second chip is mounted on the first chip in a flip chip manner, or
wherein a first chip pad of the first chip and a second chip pad of the second chip are in contact with each other.

11. The semiconductor package of claim 1, further comprising:
a second chip structure mounted on the first substrate and horizontally spaced apart from the first chip structure; and
a second substrate on which the first substrate is mounted,
wherein the second chip structure includes:
a chip stack including third chips that are vertically stacked; and
a fourth chip spaced apart from the chip stack.

12. A semiconductor package comprising:
a package substrate;
an interposer substrate mounted on the package substrate;
a first chip mounted on the interposer substrate, the first chip including a photonic integrated circuit (PIC);
a second chip on the first chip, the second chip including an electronic integrated circuit (EIC);
a transparent layer on the first chip, the transparent layer being spaced apart horizontally from the second chip;
a microlens layer disposed on the transparent layer;
a first molding layer surrounding the second chip, the transparent layer, and the microlens layer on the first chip;
a chip stack and a third chip spaced apart from the first chip on the interposer substrate; and
a second molding layer surrounding the first chip, the first molding layer, the chip stack, and the third chip on the interposer substrate,
wherein the chip stack includes fourth chips that are vertically stacked,
wherein the semiconductor package further comprises a first insulating layer on an upper surface of the transparent layer,
wherein the semiconductor package further comprises a second insulating layer on a lower surface of the microlens layer, and
wherein the first insulating layer and the second insulating layer are in contact with each other, and the first insulating layer and the second insulating layer are integrally formed of the same first material.

13. The semiconductor package of claim 12, wherein a lower surface of the transparent layer is in contact with an upper surface of the first chip.

14. The semiconductor package of claim 12, further comprising:
a third insulating layer provided on an upper surface of the first chip; and
a fourth insulating layer provided on a lower surface of the transparent layer,
wherein the third insulating layer and the fourth insulating layer are in contact with each other, and the third insulating layer and the fourth insulating layer are integrally formed of the same second material.

15. The semiconductor package of claim 12, wherein the transparent layer includes silicon (Si).

16. The semiconductor package of claim 12, wherein each of the first insulating layer and the second insulating layer has a thickness of 1 nm to 100 nm.

17. The semiconductor package of claim 12, wherein the first insulating layer and the second insulating layer include an oxide of a material constituting the transparent layer, a nitride of the material constituting the transparent layer, or an oxynitride of the material constituting the transparent layer.

18. The semiconductor package of claim 12, wherein the first chip further includes a sensor positioned below the transparent layer, and
wherein the sensor is configured to receive light that is incident on the microlens layer and transmitted through the transparent layer.

19-20. (canceled)
